(19) United States
(12) Patent Application Publication
(10) Pub. No.: US 2019/0057860 A1
(43) Pub. Date: Feb. 21, 2019

(54) METHODS FOR IMPROVING PERFORMANCE IN HAFNIUM OXIDE-BASED FERROELECTRIC MATERIAL USING PLASMA AND/OR THERMAL TREATMENT

(71) Applicant: LAM RESEARCH CORPORATION, Fremont, CA (US)

(72) Inventors: Hyungsuk Alexander YOON, San Jose, CA (US); Zhongwei Zhu, Sunnyvale, CA (US); Hwan Sung Choe, Albany, CA (US)

(21) Appl. No.: 16/052,963

(22) Filed: Aug. 2, 2018

Related U.S. Application Data
(60) Provisional application No. 62/593,530, filed on Dec. 1, 2017.
(60) Provisional application No. 62/547,360, filed on Aug. 18, 2017.

(51) Int. Cl. H01L 21/02; H01J 37/32; H01L 21/3115; H01L 49/02; H01L 27/11507; H01L 21/285; H01L 27/1159; H01L 29/51; H01L 21/28; H01L 29/66; H01L 29/78

(52) U.S. Cl. CPC H01L 21/02181; H01L 21/32133; H01L 21/0234; H01L 21/0228; H01L 21/3115; H01L 28/60; H01L 27/11507; H01L 21/02332; H01L 21/28568; H01L 27/1159; H01L 29/516; H01L 29/517; H01L 21/28291; H01L 29/6684; H01L 29/78391; H01L 29/513; H01J 2237/332; H01J 37/32091

(57) ABSTRACT

A method of forming ferroelectric hafnium oxide (HfO₂) in a substrate processing system includes arranging a substrate within a processing chamber of the substrate processing system, depositing an HfO₂ layer on the substrate, performing a plasma treatment of the HfO₂ layer, and annealing the HfO₂ layer to form ferroelectric hafnium HfO₂.

### CROSS-REFERENCE TO RELATED APPLICATIONS

This application claims the benefit of U.S. Provisional Application No. 62/593,530, filed on Dec. 1, 2017, and U.S. Provisional Application No. 62/547,360, filed on Aug. 18, 2017. The entire disclosures of the applications referenced above are incorporated herein by reference.

### FIELD

The present disclosure relates to methods for processing substrates, and more particularly to methods for improving performance in devices including hafnium oxide-based ferroelectric material using plasma and/or thermal treatment.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

The discovery of ferroelectric behavior in hafnium oxide (HfO₂)-based materials rejuvenated research into ferroelectric memory (FeRAM). Conventional ferroelectric materials such as lead zirconate titanate (PZT) do not have an adequate switching window for thicknesses below 50 nanometers (nm). Therefore PZT cannot be used for devices having features sizes that are less than 50 nm (e.g., a film thinner than 50 nm).

HfO₂ has excellent ferroelectric switching hysteresis down to thicknesses of 5 nm due to a high coercive field. HfO₂ is also a good candidate for 3D memory structures. HfO₂ has been widely used in CMOS technology as a gate dielectric. In these applications, HfO₂ is deposited using conformal atomic layer deposition (ALD). Therefore, HfO₂ may be suitable for integration into 3D FeRAM using the current 3D NAND integration schemes.

### SUMMARY

A method of forming ferroelectric hafnium oxide (HfO₂) in a substrate processing system includes arranging a substrate within a processing chamber of the substrate processing system, depositing an HfO₂ layer on the substrate, performing a plasma treatment of the HfO₂ layer, and annealing the HfO₂ layer to form ferroelectric hafnium HfO₂.

In other features, the HfO₂ layer is deposited using atomic layer deposition (ALD). The method further includes doping the HfO₂ layer. Doping the HfO₂ layer includes doping the HfO₂ layer with at least one of silicon, aluminum, yttria, lanthanum, and zirconium. Doping the HfO₂ layer includes doping the HfO₂ layer with between 0 to 60 mol % of a dopant species. Depositing the HfO₂ layer includes alternating cycles of depositing HfO₂ onto the substrate and doping the deposited HfO₂. A thickness of the HfO₂ layer is between 6 and 12 nm. Alternating cycles of depositing the HfO₂ layer and performing the plasma treatment of the HfO₂ layer.

In other features, performing the plasma treatment includes using at least one plasma gas species to perform the plasma treatment. The at least one plasma gas species includes at least one of molecular nitrogen (N₂), ammonia (NH₃), molecular oxygen (O₂), ozone (O₃), argon (Ar), and argon and molecular hydrogen (Ar/H₂). Performing the plasma treatment includes performing the plasma treatment with molecular nitrogen (N₂), and performing the plasma treatment with N₂ causes HfO_{X}N_{y} to form on a surface of the HfO₂ layer.

In other features, performing the plasma treatment includes performing the plasma treatment for between 15 and 60 seconds. Performing the plasma treatment includes performing the plasma treatment at a radio frequency (RF) power between 500 and 1200 watts. The RF power is provided at between 1 and 15 MHz. Annealing the HfO₂ layer includes annealing the HfO₂ layer at a temperature between 500 and 1100° C. Annealing the HfO₂ layer includes annealing the HfO₂ layer at a temperature between 800 and 1000° C. Depositing a top electrode on the HfO₂ layer prior to the annealing. The top electrode comprises at least one of tantalum nitride, titanium nitride, and tungsten. Depositing the HfO₂ layer on the substrate includes depositing the HfO₂ layer on one of an underlying layer and a bottom electrode formed on the substrate.

A method of treating a substrate including ferroelectric hafnium oxide (HfO₂) in a substrate processing system includes arranging a substrate including an insulator layer within a processing chamber of the substrate processing system, performing at least one of a thermal treatment and a plasma treatment of the insulator layer, depositing an HfO₂ layer on the insulator layer, and annealing the HfO₂ layer to form ferroelectric hafnium HfO₂.

In other features, the insulator layer includes one of silicon dioxide (SiO₂) and silicon oxynitride (SiON). Performing the at least one of the thermal treatment and the plasma treatment includes sequentially performing the thermal treatment and the plasma treatment. Performing the at least one of the thermal treatment and the plasma treatment includes increasing a temperature of the substrate to between 200 and 600° C. for 1 to 30 minutes. Performing the at least one of the thermal treatment and the plasma treatment includes providing at least one of N₂, N₂/H₂, NH₃, O₂, and O₃ to the processing chamber.

In other features, the method further includes performing a plasma treatment of the HfO₂ layer. The HfO₂ layer is deposited using atomic layer deposition (ALD). The method further includes doping the HfO₂ layer.

A method of treating a substrate including ferroelectric hafnium oxide (HfO₂) in a substrate processing system includes arranging a substrate including an insulator layer within a processing chamber of the substrate processing system, depositing at least one first HfO₂ layer on the insulator layer, performing at least one of a thermal treatment and a plasma treatment of the at least one first HfO₂ layer, depositing at least one second HfO₂ layer on the at least one first HfO₂ layer, and annealing the at least one second HfO₂ layer and the at least one first HfO₂ layer to form a ferroelectric hafnium HfO₂ layer.

In other features, the insulator layer includes one of silicon dioxide (SiO₂) and silicon oxynitride (SiON). Performing the at least one of the thermal treatment and the plasma treatment includes sequentially performing the thermal treatment and the plasma treatment. Performing the at least one of the thermal treatment and the plasma treatment includes increasing a temperature of the substrate to between 200 and 600° C. for 1 to 30 minutes. Performing the at least one of the thermal treatment and the plasma treatment includes providing at least one of N₂, N₂/H₂, NH₃, O₂, and O₃ to the processing chamber.

In other features, the at least one first HfO₂ layer is deposited in accordance with a dose time that is greater than a dose time used to deposit the at least one second HfO₂ layer. The method further includes performing at least one of a thermal treatment and a plasma treatment of the insulator layer prior to depositing the at least one first HfO₂ layer. The at least one first HfO₂ layer and the at least one second HfO₂ layer are deposited using atomic layer deposition (ALD).

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1A and 1B are side cross-sectional views of substrates including nitridated HfO₂ according to the present disclosure;

FIG. 2 is a flowchart of an example of a method for reducing leakage current in HfO₂ based ferromagnetic material according to the present disclosure;

FIG. 3 is a flowchart of an example of a method for depositing and doping the HfO₂ according to the present disclosure;

FIG. 4 is a functional block diagram of an example of a substrate processing chamber for depositing, optional doping and nitridating the HfO₂ according to the present disclosure;

FIG. 5 is a side cross-sectional view of a substrate including a stack including a metal layer, a ferromagnetic layer, an insulator layer and a semiconductor layer according to the present disclosure;

FIG. 6 is a flowchart of an example of a method for depositing, optional doping and nitridating the HfO₂ in the substrate of FIG. 5;

FIG. 7 is a flowchart of an example of another method for depositing, optional doping and plasma treatment of a substrate according to the present disclosure;

FIG. 8 is a flowchart of an example of another method for depositing, optional doping and plasma treatment of a substrate according to the present disclosure;

FIG. 9 is a flowchart of an example of a method for depositing, doping and plasma treatment of a substrate according to the present disclosure;

FIG. 10 is a functional block diagram of a substrate processing system using transformer coupled plasma for performing plasma treatment;

FIGS. 11A, 11B, 11C, 11D, 11E, and 11F are side cross-sectional views of an example process including pretreatment of an insulator layer according to the present disclosure;

FIGS. 12A, 12B, 12C, 12D, 12E, and 12F are side cross-sectional views of an example process including treatment of one or more HfO₂ layers according to the present disclosure; and

FIG. 13 is a flowchart of an example of a method for pretreating an insulator layer and/or treating one or more HfO₂ layers according to the present disclosure.

In the drawings, reference numbers may be reused to identify similar and/or identical elements.

### DETAILED DESCRIPTION

However, thermal stability of HfO₂ is an obstacle for commercialization in FeRAM applications. Although temperatures of 600-650° C. are high enough to crystallize as-deposited amorphous HfO₂ into the ferroelectric phase, many integration schemes require a thermal budget of at least 1000° C. The higher process temperature degrades HfO₂ -based FeRAM by increasing leakage current and/or shorting the devices.

Sources of leakage after high temperature annealing include defect generation at a top electrode/HfO₂ interface. Another source of leakage current includes film cracking of HfO₂. With the cracking of HfO₂ , atoms from the top and bottom electrodes (typically TiN) can freely diffuse into HfO₂ , which eventually causes failure of the device.

A method according to the present disclosure reduces leakage current in HfO₂ -based ferroelectric material. In addition to other steps described further below, the method according to the present disclosure includes depositing doped or undoped HfO₂ on an underlying layer and performing plasma treatment of the HfO₂ film using molecular nitrogen (N₂), ammonia (NH₃), molecular oxygen (O₂), ozone (O₃), argon (Ar), and/or argon and molecular hydrogen (Ar/H₂) plasma. A top electrode such as titanium nitride (TiN), tantalum nitride (TaN), iridium (Ir), or tungsten (W) is then deposited on the treated HfO₂ film. The substrate is annealed using rapid thermal annealing at a predetermined temperature in a range from 500° C. to 1100° C. A similar approach can be used for stacks including metal, ferromagnetic, insulator and semiconductor (MFIS) layers.

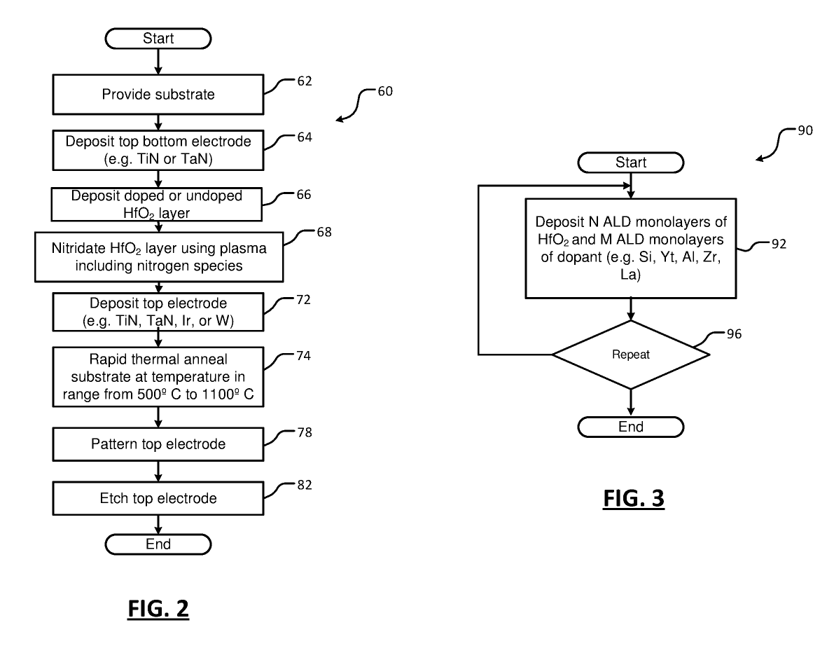

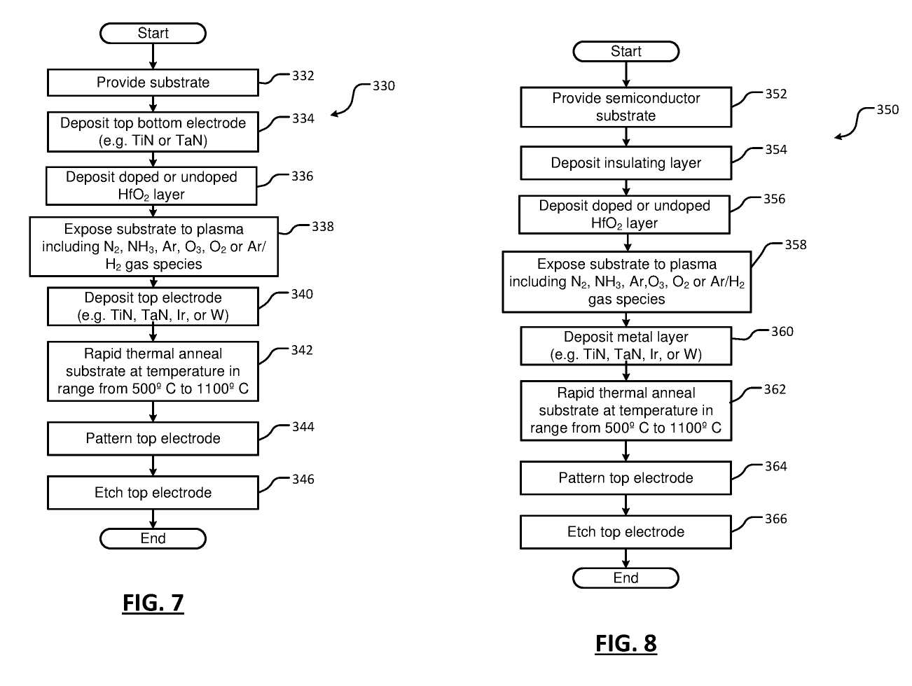

Plasma treatment is used to improve the thermal stability of HfO₂-based ferroelectric material. The plasma treatment densifies the HfO₂ film, which shrinks (less volume) and cracks less during subsequent high-temperature annealing. In FIGS. 2, 3 and 6, the plasma treatment includes nitridation. In FIGS. 7-9, other plasma treatments using Ar, Ar/H₂, O₂, O₃, and/or NH₃ are disclosed.

For example, use of N₂ plasma forms HfOₓN_{y} at the surface of the HfO₂. The nitridation of the surface of the HfO₂ reduces the generation of defects at the top electrode/HfO₂ interface in the subsequent processing steps, which mitigates the leakage current.

In other examples, pretreating the substrate with a plasma and/or thermal treatment process prior to and/or between cycles of ALD of HfO₂ further reduces leakage and widens a memory window of the device.

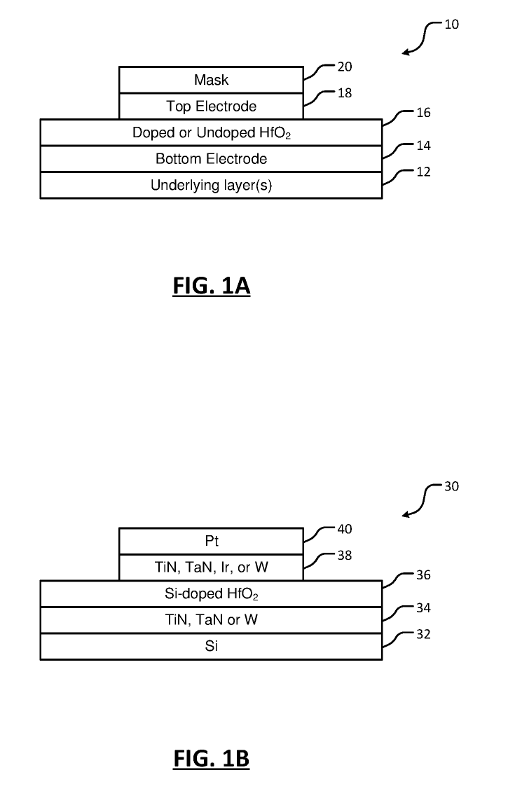

Referring now to FIGS. 1A and 1B, examples of devices including hafnium oxide (HfO₂)-based ferroelectric material according to the present disclosure are shown. In FIG. 1A, a substrate 10 includes one or more underlying layers 12 and a bottom electrode 14 arranged on the underlying layer 12. In some examples, the bottom electrode 14 includes titanium nitride (TiN), tantalum nitride (TaN), iridium (Ir), or tungsten (W), although other electrode materials can be used. In some examples, the bottom electrode 14 is deposited using atomic layer deposition (ALD), chemical vapor deposition (CVD) or physical vapor deposition (PVD).

A HfO₂ layer 16 is deposited. In some examples, the deposited HfO₂ layer 16 has a thickness in a range from 5 nm to 12 nm. In some examples, the HfO₂ layer 16 is doped using a dopant species selected from a group consisting of silicon (Si), aluminum (Al), yttrium (Yt), zirconium (Zr), and/or lanthanum (La). In some examples, the HfO₂ layer 16 is deposited using atomic layer deposition (ALD), although other processes can be used. For example, thermal ALD or plasma-enhanced ALD can be used. In some examples, the HfO₂ layer 16 is undoped. In other examples, the HfO₂ layer 16 is doped to a predetermined doping level from greater than 0 mol % to less than or equal to 60 mol % of the selected dopant species. In some examples, the HfO₂ layer 16 is doped to a predetermined doping level from 3 mol % to 5 mol % of the selected dopant species.

In some examples, T ALD supercycles are performed to deposit the doped HfO₂ layer, where T is an integer greater than one. Each ALD supercycle includes N ALD HfO₂ cycles and M ALD cycles of the dopant species, where T, N and M are integers greater than zero. The N ALD HfO₂ cycles and M ALD cycles of the dopant species within each of the supercycles can be performed in any order. In some examples, the plasma treatment is performed between two or more of the T supercycles and/or after the T supercycles.

Plasma treatment of the HfO₂ layer 16 is performed. For example, the HfO₂ layer 16 is nitridated by plasma including a nitrogen gas species. For example, molecular nitrogen (N₂) gas may be used. In some examples, the nitridation is performed during a predetermined period in a range from 15 s to 60 s. In some examples, the RF power may be in a range from 100 W to 15 kW. In some examples, the plasma power is in a range from 500 W to 1200 W. In some examples, the RF frequency may be in a range from 1 MHz to 15 MHz. In some examples, the RF frequency is 2.0 MHz and/or 13.56 MHz.

After nitridation, a top electrode 18 is deposited on the HfO₂ layer 16. In some examples, the top electrode 18 includes TiN, TaN, Ir or W, although other electrode materials can be used. In some examples, the top electrode 18 is deposited using atomic layer deposition (ALD), chemical vapor deposition (CVD) or physical vapor deposition (PVD).

After depositing the top electrode 18, the substrate 10 is annealed at a predetermined temperature in a range from 500° C. to 1100° C. In other examples, the annealing temperature is in a range from 800° C. to 1000° C. After annealing, the top electrode 18 is patterned. For example, a mask 20 may be used. The top electrode is etched using wet etching or dry etching. In some examples, the mask 20 is optionally removed after etching. In other examples, the mask is not removed.

In FIG. 1B, a specific example of the device is shown. A substrate 30 includes a silicon (Si) layer 32. A bottom electrode 34 made of TiN is arranged on the Si layer 32. A Si-doped HfO₂ layer 36 is deposited on the bottom electrode 34. The Si-doped HfO₂ layer 36 is treated using one of the plasma treatments described herein and then a top electrode 38 made of TiN is deposited on the Si-doped HfO₂ layer 36. The substrate 30 is annealed at a predetermined temperature. The top electrode 38 is patterned using an inert metal layer 40 such as platinum (Pt) and etched using wet or dry etching.

Referring now to FIG. 2, a method 60 includes providing a substrate. At 64, a bottom electrode layer (including TiN, TaN, Ir or W) is deposited on the substrate. At 66, a doped or undoped HfO₂ layer is deposited on the bottom electrode layer. At 68, the HfO₂ layer is nitridated using plasma and a nitrogen species. At 72, a top electrode layer (including TiN, TaN, Ir or W) is deposited on the nitridated HfO₂ layer. At 74, the substrate is processed using rapid thermal annealing to a temperature in a range from 500° C. to 1100° C. In some examples, the top electrode is patterned at 78 and etched at 82.

Referring now to FIG. 3, a method 90 for depositing the doped HfO₂ layer using T ALD supercycles is shown. At 92, N ALD HfO₂ cycles are performed and M ALD cycles of the dopant species are performed (where T, N and M are integers greater than zero). As can be appreciated, the N ALD HfO₂ cycles and the M ALD cycles of the dopant species can be performed in any order during a given supercycle. At 96, the method returns to 92 if additional supercycles need to be performed or ends if the T supercycles are completed.

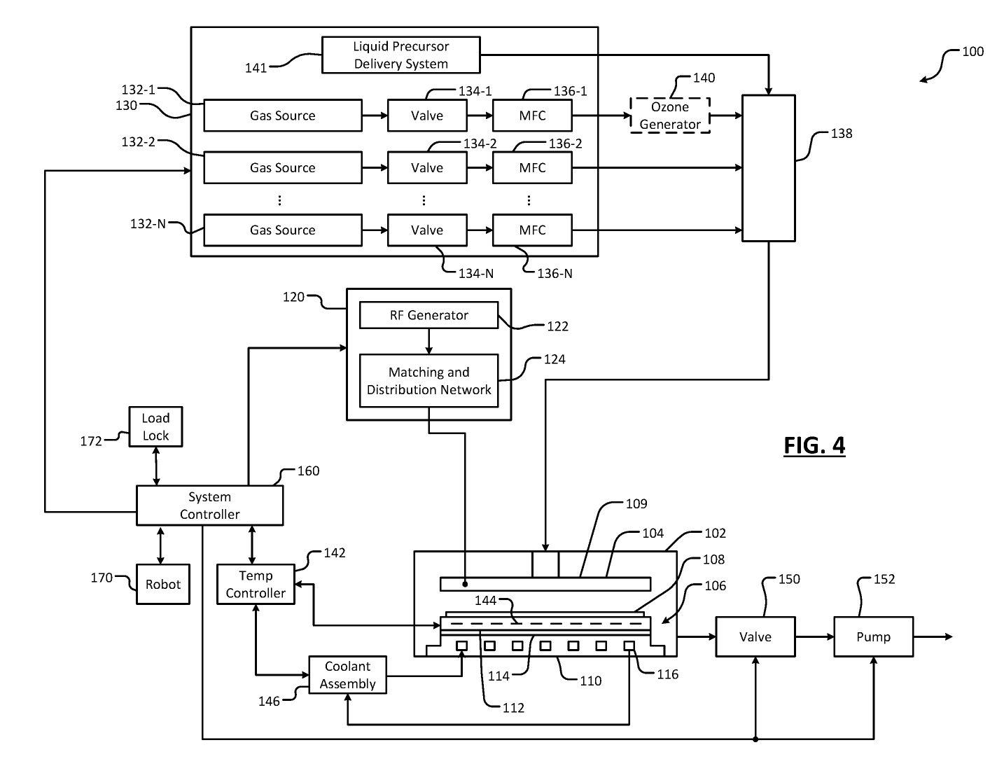

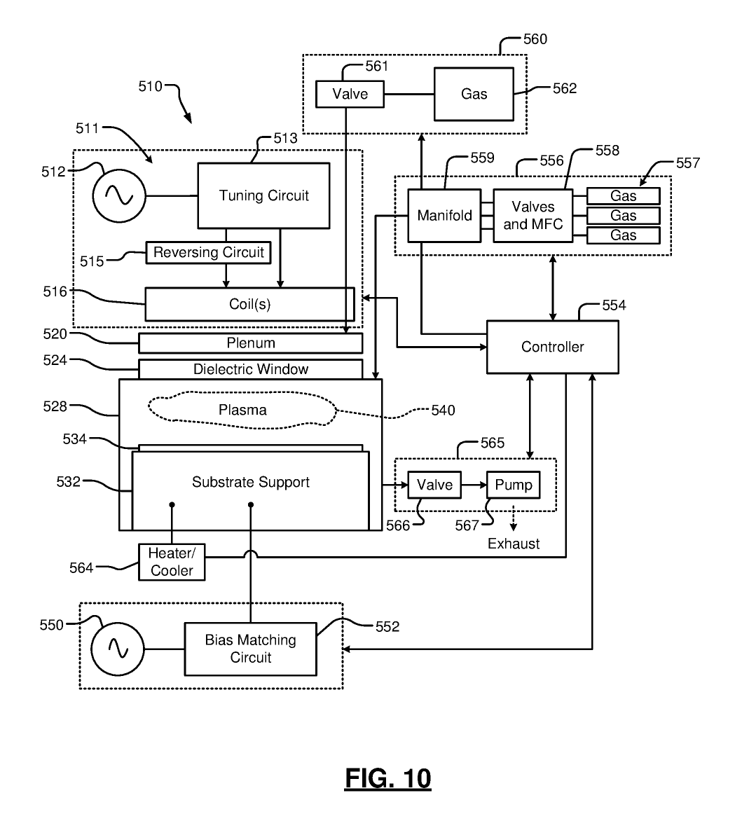

Referring now to FIG. 4, an example substrate processing system 100 for depositing and optionally doping the HfO₂ layer using atomic layer deposition (ALD) and nitridating the HfO₂ layer is shown. While the deposition and doping of the HfO₂ layer and subsequent nitridation are being performed in the same processing chamber in this example, separate processing chambers can be used. For example, nitridation can also be performed in a transformer coupled plasma (TCP) chamber (e.g. as shown in FIG. 10), a plasma-enhanced chemical vapor deposition (PECVD) chamber, a high pressure CVD (HPCVD) chamber, and/or a chamber using a remote plasma source.

The substrate processing system 100 includes a processing chamber 102 that encloses other components of the substrate processing chamber 100 and contains the RF plasma. The substrate processing chamber 100 includes an upper electrode 104 and a substrate support, such as an electrostatic chuck (ESC) 106. During operation, a substrate 108 is arranged on the ESC 106.

For example only, the upper electrode 104 may include a showerhead 109 that introduces and distributes process gases. The showerhead 109 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 104 may include a conducting plate and the process gases may be introduced in another manner.

The ESC 106 includes a conductive baseplate 110 that acts as a lower electrode. The baseplate 110 supports a heating plate 112, which may correspond to a ceramic multi-zone heating plate. A thermal resistance layer 114 may be arranged between the heating plate 112 and the baseplate 110. The baseplate 110 may include one or more coolant channels 116 for flowing coolant through the baseplate 110.

An RF generating system 120 generates and outputs an RF voltage to one of the upper electrode 104 and the lower electrode (e.g., the baseplate 110 of the ESC 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely.

A gas delivery system 130 includes one or more gas sources 132-1, 132-2, . . . , and 132-N (collectively gas sources 132), where N is an integer greater than zero. The gas sources supply one or more deposition precursors and mixtures thereof. The gas precursors may include precursor gases for the HfO₂ layer and/or other layers. The gas sources may also supply purge gas and gases including a nitrogen species for plasma nitridation and/or other gas species (such as Ar, Ar/H₂, NH₃, O₂, O₃, etc.) for other plasma treatments. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 138. An output of the manifold 138 is fed to the processing chamber 102. For example only, the output of the manifold 138 is fed to the showerhead 109. In some examples, an optional ozone generator 140 may be provided between the mass flow controllers 136 and the manifold 138. In some examples, the substrate processing system 100 may include a liquid precursor delivery system 141. The liquid precursor delivery system 141 may be incorporated within the gas delivery system 130 as shown or may be external to the gas delivery system 130. The liquid precursor delivery system 141 is configured to provide precursors that are liquid and/or solid at room temperature via a bubbler, direct liquid injection, vapor draw, etc.

A temperature controller 142 may be connected to a plurality of thermal control elements (TCEs) 144 arranged in the heating plate 112. For example, the TCEs 144 may include, but are not limited to, respective macro TCEs corresponding to each zone in a multi-zone heating plate and/or an array of micro TCEs disposed across multiple zones of a multi-zone heating plate as described in more detail in FIGS. 2A and 2B. The temperature controller 142 may be used to control the plurality of TCEs 144 to control a temperature of the ESC 106 and the substrate 108.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the ESC 106.

A valve 150 and pump 152 may be used to evacuate reactants from the processing chamber 102. A system controller 160 may be used to control components of the substrate processing system 100. A robot 170 may be used to deliver substrates onto, and remove substrates from, the ESC 106. For example, the robot 170 may transfer substrates between the ESC 106 and a load lock 172. Although shown as separate controllers, the temperature controller 142 may be implemented within the system controller 160. The temperature controller 142 may be further configured to implement one or more models to estimate temperatures of the ESC 106 according to the principles of the present disclosure.

Generally, more nitrogen is incorporated into the HfO₂ surface at high plasma power, accompanied by less film cracking. However, the leakage current may not strictly follow the amount of incorporated nitrogen. For example, one sample treated by 1000 W plasma may be leakier than another sample treated by only 500 W. Higher plasma power may also damage the HfO₂ film structure, which in turn increases leakage current. In addition, since HfN is not ferroelectric, the plasma nitridation process may decrease remnant polarization (Pr).

Conversely, extending the plasma time at 500 W reduces the leakage current after 1000° C./1 s anneal, while a period of 15 s may not be sufficient to mitigate the leakage current. For example, HfO₂ is typically over-nitridated after 60 s plasma while the leakage current is as low as 10⁻⁸ A. However, the ferroelectric property of the HfO₂ may be severely degraded (e.g., Pr=7 μC/cm²) when the plasma time is greater than 60 s.

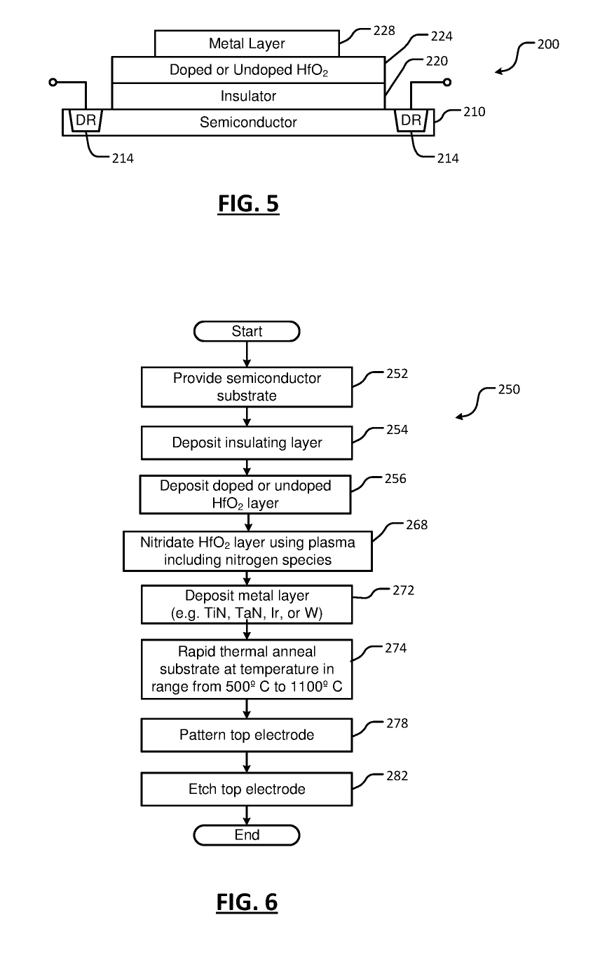

Referring now to FIG. 5, nitridation and optional doping of HfO₂ can also be used for stacks including metal, ferromagnetic, insulator, and semiconductor (MFIS) layers. A substrate 200 includes one or more underlying layers such as a semiconductor layer 210 that may include one or more diffusion regions 214. An insulator layer 220 is deposited on the semiconductor layer 210. In some examples, the insulator layer 220 includes silicon dioxide (SiO₂) or silicon nitride (SiN). A ferromagnetic layer including doped or undoped HfO₂ layer 224 (as described above) is deposited on the insulator layer 220. The doped or undoped HfO₂ layer 224 is processed using the selected plasma treatment. A metal layer 228 is deposited on the doped or undoped HfO₂ layer 224. In some examples, the metal layer 228 includes TiN, TaN, Ir or W. After depositing the metal layer 228, the substrate is annealed using rapid thermal annealing at a temperature in a range from 500° C. to 1100° C.

Referring now to FIG. 6, a method 250 for depositing, optional doping and nitridating the HfO₂ in the stack of FIG. 5 is shown. At 252, a semiconductor substrate is provided. At 254, an insulator layer is deposited on the semiconductor substrate. In some examples, the insulator layer includes silicon dioxide (SiO₂) or silicon nitride (SiN). At 256, a doped or undoped HfO₂ layer is deposited on the insulator layer. At 268, the HfO₂ layer is nitridated using plasma including nitrogen species. At 272, a metal layer is deposited on the HfO₂ layer. In some examples, the metal layer includes TiN, TaN, Ir or W. At 274, rapid thermal annealing is performed on the substrate at a temperature in a range from 500° C. to 1100° C. In some examples, the metal layer is patterned at 278 and etched at 282.

In some examples, the insulator layer, the doped or undoped HfO₂ layer, and the nitridation are performed in the same processing chamber or using different processing chambers. The insulator layer, the doped or undoped HfO₂ layer, and/or the metal layer can be deposited using any of the processes described above.

Referring now to FIG. 7, other gas species can be used during plasma treatment of the substrate to reduce leakage current. More particularly, gas species including ammonia (NH₃), molecular oxygen (O₂), argon (Ar) or a mixture of argon and molecular hydrogen (Ar/H₂) can be used. In FIG. 7, a method 330 includes providing a substrate. At 332, a bottom electrode layer (including TiN, TaN, Ir or W) is deposited on the substrate. At 336, a doped or undoped HfO₂ layer is deposited on the bottom electrode layer. At 338, the HfO₂ layer is treated using plasma with a plasma gas species selected from a group consisting of N₂, NH₃, O₂, O₃, Ar and/or Ar/H₂. At 340, a top electrode layer (including TiN, TaN, Ir or W) is deposited on the nitridated HfO₂ layer. At 342, the substrate is processed using rapid thermal annealing to a temperature in a range from 500° C. to 1100° C. The top electrode is patterned at 344 and etched at 346.

Referring now to FIG. 8, a method 350 for depositing, optional doping and plasma treating the HfO₂ in the stack of FIG. 5 is shown. At 352, a semiconductor substrate is provided. At 354, an insulator layer is deposited on the semiconductor substrate. In some examples, the insulator layer includes silicon dioxide (SiO₂) or silicon nitride (SiN). At 356, a doped or undoped HfO₂ layer is deposited on the insulator layer. At 358, the HfO₂ layer is treated using plasma with a plasma gas species selected from a group consisting of N₂, NH₃, Ar, O₂, and/or Ar/H₂. At 360, a metal layer is deposited on the HfO₂ layer. In some examples, the metal layer includes TiN, TaN, Ir or W. At 362, rapid thermal annealing is performed on the substrate at a temperature in a range from 500° C. to 1100° C. In some examples, the metal layer is patterned at 364 and etched at 366.

In some examples, the insulator layer, the doped or undoped HfO₂ layer, and the plasma treatment are performed in the same processing chamber or using different processing chambers. The insulator layer, the doped or undoped HfO₂ layer, and/or the metal layer can be deposited using any of the processes described above.

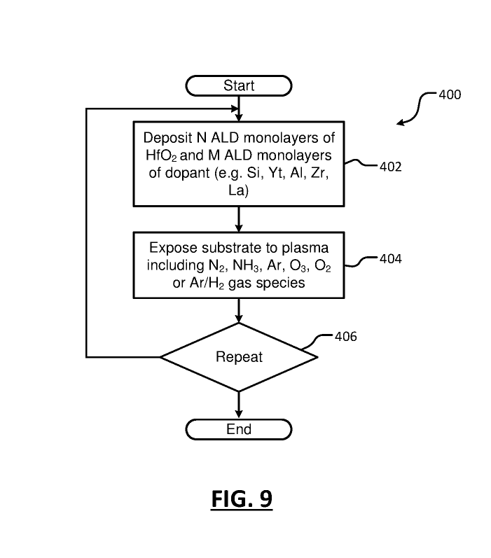

Referring now to FIG. 9, a method 400 for depositing the doped HfO₂ layer using T ALD supercycles with intervening plasma treatment is shown. At 402, N ALD HfO₂ cycles are performed and M ALD cycles of the dopant species are performed, where T, N and M are integers greater than zero. As can be appreciated, the N ALD HfO₂ cycles and the M ALD cycles of the dopant species can be performed in any order during a given supercycle. At 404, the HfO₂ layer is treated using plasma with a plasma gas species selected from a group consisting of N₂, NH₃, Ar, O₂ O₃, and/or Ar/H₂. At 406, the method returns to 402 if additional supercycles need to be performed or ends if the T supercycles are completed.

Referring now to FIG. 10, an example of a substrate processing system 510 for performing TCP plasma treatment according to the present disclosure is shown. The substrate processing system 510 includes a coil driving circuit 511. In some examples, the coil driving circuit 511 includes an RF source 512 and a tuning circuit 513. The tuning circuit 513 may be directly connected to one or more inductive coils 16. Alternatively, the tuning circuits 513 may be connected by an optional reversing circuit 515 to one or more of the coils 516. The tuning circuit 513 tunes an output of the RF source 512 to a desired frequency and/or a desired phase, matches an impedance of the coils 516 and splits power between the TCP coils 516. The reversing circuit 515 is used to selectively switch the polarity of current through one or more of the TCP coils 516. Examples of the reversing circuit 515 are shown and described in commonly assigned U.S. patent application Ser. No. 14/673,174 by Sato et al., titled “Systems And Methods For Reversing RF Current Polarity At One Output Of A Multiple Output RF Matching Network,” filed Mar. 30, 2015.

In some examples, a plenum 520 may be arranged between the TCP coils 516 and a dielectric window 524 to control the temperature of the dielectric window with hot and/or cold air flow. The dielectric window 524 is arranged along one side of a processing chamber 528. The processing chamber 528 further comprises a substrate support (or pedestal) 532. The substrate support 532 may include an electrostatic chuck (ESC), or a mechanical chuck or other type of chuck. Process gas is supplied to the processing chamber 528 and plasma 540 is generated inside of the processing chamber 528. The plasma 540 etches an exposed surface of the substrate 534. An RF source 550 and a bias matching circuit 552 may be used to bias the substrate support 532 during operation to control ion energy.

A gas delivery system 556 may be used to supply a process gas mixture to the processing chamber 528. The gas delivery system 556 may include process and inert gas sources 557, a gas metering system 558 such as valves and mass flow controllers, and a manifold 559. A gas delivery system 560 may be used to deliver gas 562 via a valve 561 to the plenum 520. The gas may include cooling gas (air) that is used to cool the TCP coils 516 and the dielectric window 524. A heater/cooler 564 may be used to heat/cool the substrate support 532 to a predetermined temperature. An exhaust system 565 includes a valve 566 and pump 567 to remove reactants from the processing chamber 528 by purging or evacuation.

A controller 554 may be used to control the etching process. The controller 554 monitors system parameters and controls delivery of the gas mixture, striking, maintaining and extinguishing the plasma, removal of reactants, supply of cooling gas, and so on. Additionally, as described below in detail, the controller 554 may control various aspects of the coil driving circuit 511, the RF source 550, and the bias matching circuit 552, etc.

### EXAMPLES

Plasma treatment of the HfO₂ in a TCP chamber was tested at 4.2 mol % Si doping. The as-deposited HfO₂ exhibited leakage current at the level of 10⁻⁷ A after 1000° C./1 sec anneal. Treatment with N₂ plasma decreased the leakage current by one order of magnitude, down to 10⁻⁸ A using the same 1000° C./1 sec anneal. Other plasma treatments using NH₃, Ar, and Ar/H₂ gas species were also tested. NH₃ and Ar/H₂ plasma treatment decreased the leakage current by a factor of 2 after 1000° C./1 sec anneal. At lower anneal temperatures (e.g. 800° C.), all of the plasma treatments (N₂, NH₃, Ar, and Ar/H₂) improved the leakage current as compared to the sample without plasma treatment. Plasma nitridation slightly degraded the remnant polarization (Pr) of the ferroelectric HfO₂. However, the Pr value (15-17 μC/cm²) still meets the target spec of 15 μC/cm². The same results are achieved with NH₃ and Ar/H₂ plasma.

A sample with higher doping (e.g. 5.7 mol % Si in HfO₂ ) was also studied with the same plasma treatments. The higher doping concentration is not optimal due to the wakeup effect in the initial cycles. The N₂ plasma improved leakage current in the HfO₂ with 5.7 mol % Si. whereas NH₃, Ar, and Ar/H₂ plasma increased the leakage current. The samples treated with Ar and Ar/H₂ plasma fail with only 1000 switching cycles.

While plasma treatment of HfO₂ before top electrode deposition mitigates the defects at the HfO₂ surface, the defects in the bulk HfO₂ film may be another leakage current source. As a result, some of the methods described herein employ plasma treatment between the supercycles of HfO₂ deposition to further mitigate the defects within the film. For example, rather than one single plasma treatment after 8 nm HfO₂ , the substrate is exposed to the plasma treatment after every 1, 2, or 4 nm of HfO₂ deposition.

In addition to N₂ plasma, Ar/H₂ and NH₃ plasma also decrease the leakage current in HfO₂ after 1000° C. anneal. N₂ plasma is the most effective environment in leakage current improvement. Supercycles of HfO₂ deposition and plasma treatment have the potential to further decrease leakage current in the ferroelectric material. In other examples, the type of plasma can be varied to capacitively coupled plasma (CCP), downstream or remote plasma, or microwave plasma.

### Pretreating Substrate and/or Treating HfO₂ Layers

In other examples, pretreating the substrate with a plasma and/or thermal treatment process prior to and/or between cycles of ALD of HfO₂ further reduces leakage and widens a memory window of the device. For example, in a ferroelectric field-effect transistor (FeFET), ferroelectric HfO₂ is arranged between a metal layer (e.g., a top electrode) and a dielectric layer (e.g., an insulator/interfacial layer) formed on an Si substrate to form an MFIS film stack structure. The insulator layer is critical to performance properties of the MFIS film stack. Flipping of charges in the ferroelectric material shifts a flat band voltage, causes hysteresis in C-V curves, and shifts a threshold voltage (Vth) of the transistor. Defects in the insulator layer and/or at an interface between the insulator layer and the ferroelectric material can cause charge injection, which shifts the flat band voltage and causes C-V hysteresis in an opposite direction to that of the ferroelectric material (causing cancellation of the C-V hysteresis). Accordingly, it is desirable to minimize defects in the insulator layer and/or at the interface between the insulator layer and the ferroelectric material to improve performance of the ferroelectric material.

Pretreating the substrate with a plasma and/or thermal treatment as described below reduces defects in the insulator layer and/or at the interface between the insulator layer and the ferroelectric material to reduce leakage and widen a memory window of the device as described below in more detail. Pretreatment methods include thermal treatment, plasma treatment, and/or a sequence of thermal and plasma treatment. Gas environments for the treatment may include N₂, N₂/H₂, NH₃, O₂, and/or O₃. Substrates may be pretreated in an ALD processing chamber or in a separate chamber prior to transfer to the ALD processing chamber. In some examples, the pretreatment process may be performed subsequent to performing one or more ALD cycles of HfO₂ (e.g., 0.1-2.0 nm HfO₂ ) on the surface of the insulator layer. In other examples, the pretreatment process may be performed on the substrate prior to performing ALD and subsequent to one or more cycles of ALD. Deposition conditions of the one or more ALD cycles prior to performing the treatment process may differ from deposition conditions for subsequent ALD cycles. For example, an ozone dose time of the one or more ALD cycles prior to performing the treatment process may be greater than an ozone dose time of subsequent cycles.

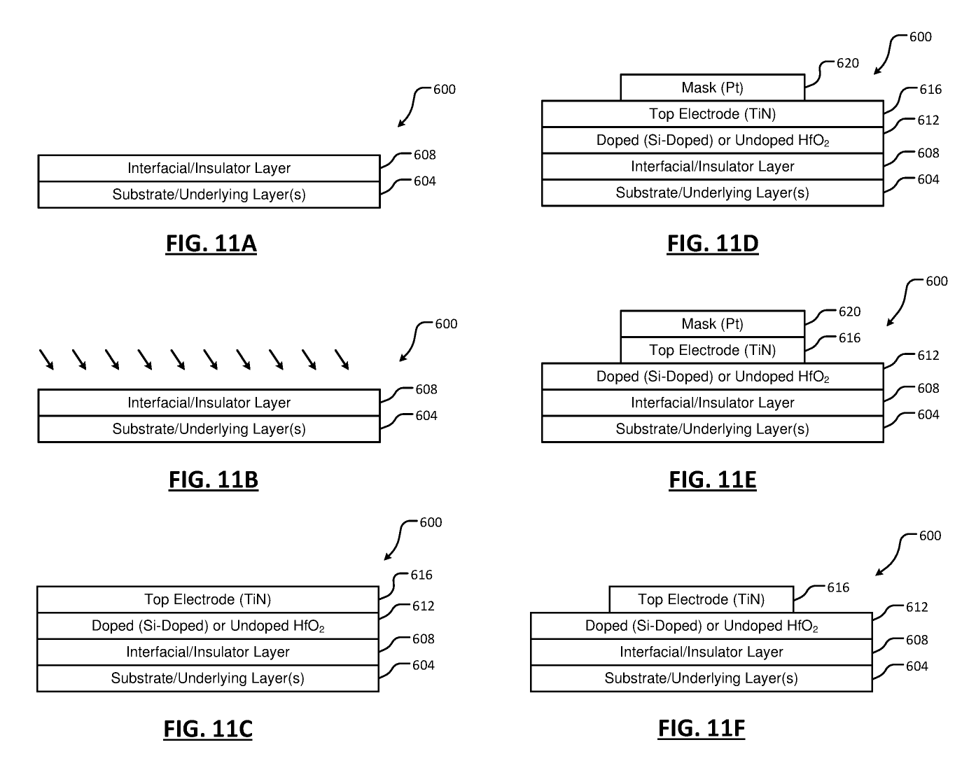

Referring now to FIGS. 11A, 11B, 11C, 11D, 11E, and 11F, an example process for forming a (HfO₂)-based ferroelectric material in a device 600 is shown. In FIG. 11A, the device 600 includes a substrate (e.g., one or more underlying layers) 604 and an interfacial/insulator layer 608 (referred to hereinafter as an insulator layer) arranged on the underlying layers 604. For example, the underlying layers 604 comprise silicon (Si). In some examples, the insulator layer 608 includes silicon dioxide (SiO₂) or silicon oxynitride (SiON) dielectrics. In some examples, the insulator layer 608 is deposited using atomic layer deposition (ALD), chemical vapor deposition (CVD) or physical vapor deposition (PVD). In other examples, the insulator layer 608 may be formed via thermal oxidation of Si. For example, the insulator layer 608 may be formed by thermal oxidation of Si in an oxygen environment with a nitrogen species (e.g., N₂O or N₂) to form SiON, plasma nitridation of SiO₂, etc. The insulator layer 608 may be deposited in a different processing chamber than a chamber used to perform subsequent steps.

As shown in FIG. 11B, pretreatment of the insulator layer 608 is performed. The pretreatment may be performed in a same or different processing chamber as the deposition of the insulator layer 608. The pretreatment may include thermal treatment, plasma treatment, and/or a sequence of thermal and plasma treatment (e.g., a thermal treatment step followed by a plasma treatment step). The pretreatment removes defects (e.g., unbonded hydrocarbon contaminants) from the surface of the insulator layer 608. For example, exposure to air may cause hydrocarbons to absorb onto the surface of the insulator layer 608. The pretreatment facilitates bonding between the hydrocarbon contaminants and gases within the processing chamber. The bonded hydrocarbons may then be removed (e.g., purged) from the processing chamber.

Thermal treatment may include increasing a temperature of the substrate (e.g., using the temperature controller 142) while flowing process gases into the processing chamber. For example, the substrate may be increased to a temperature from 200 to 600° C. from 1 to up to 30 minutes. In some examples, the substrate is increased to a temperature from 300 to 400° C. The process gases may include N₂, N₂/H₂, NH₃, O₂, and/or O₃. The increased temperature facilitates bonding between the hydrocarbon contaminants and the process gases.

Plasma treatment may include flowing process gases (N₂, N₂/H₂, NH₃, O₂, O₃, etc.) and striking plasma within the processing chamber. While the plasma treatment may be performed while the temperature of the substrate is increased, the plasma treatment may be performed at significantly lower temperatures than the thermal treatment (e.g., at 50° C.). Accordingly, the plasma treatment facilitates bonding between the hydrocarbon contaminants and the process gases without the greater temperatures of the thermal treatment. The plasma treatment may be performed from 1 to up to 30 minutes.

As shown in FIG. 11C, an HfO₂ layer 612 is deposited on the insulator layer 608 and a top electrode 616 is deposited on the HfO₂ layer 612. In some examples, the deposited HfO₂ layer 612 has a thickness in a range from 2 nm to 12 nm. In some examples, the HfO₂ layer 612 is doped using a dopant species selected from a group consisting of silicon (Si), aluminum (Al), yttrium (Yt), zirconium (Zr), and/or lanthanum (La). In some examples, the HfO₂ layer 612 is deposited using atomic layer deposition (ALD), although other processes can be used. For example, thermal ALD or plasma-enhanced ALD can be used. In some examples, the HfO₂ layer 612 is undoped. In other examples, the HfO₂ layer 612 is doped to a predetermined doping level from greater than 0 mol % to less than or equal to 60 mol % of the selected dopant species. In some examples, the HfO₂ layer 612 is doped to a predetermined doping level from 3 mol % to 5 mol % of the selected dopant species. The HfO₂ layer 612 may be amorphous.

Plasma treatment of the HfO₂ layer 612 may optionally be performed. For example, the HfO₂ layer 612 is nitridated by plasma including a nitrogen gas species. For example, molecular nitrogen (N₂) gas may be used. In some examples, the nitridation is performed during a predetermined period in a range from 15 s to 60 s. In some examples, the RF power may be in a range from 100 W to 15 kW. In some examples, the plasma power is in a range from 500 W to 1200 W. In some examples, the RF frequency may be in a range from 1 MHz to 15 MHz. In some examples, the RF frequency is 2.0 MHz and/or 13.56 MHz.

The top electrode 616 is deposited on the HfO₂ layer 612. In some examples, the top electrode 616 includes TiN, TaN, Ir or W, although other electrode materials can be used (e.g., Pt, Au, Pd, Al, Mo, Ni, Ti, etc.). In some examples, the top electrode 616 is deposited using atomic layer deposition (ALD), chemical vapor deposition (CVD), or physical vapor deposition (PVD). After depositing the top electrode 616, the device 600 is annealed at a predetermined temperature in a range from 500° C. to 1100° C. In other examples, the annealing temperature is in a range from 800° C. to 1000° C.

After annealing, the top electrode 616 is patterned as shown in FIGS. 11D, 11E, and 11F. For example, a mask 620 may be deposited as shown in FIG. 11D. The mask 620 may comprise platinum (Pt). The top electrode 616 is etched using wet etching or dry etching as shown in FIG. 11E. In some examples, the mask 620 is optionally removed after etching as shown in FIG. 11F. In other examples, the mask is not removed.

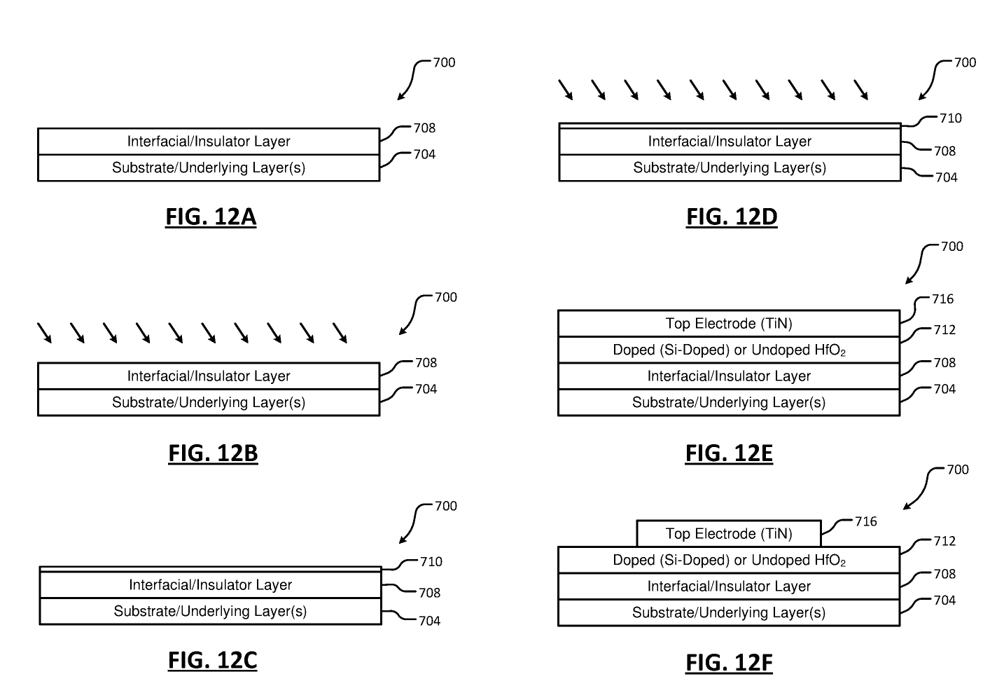

Referring now to FIGS. 12A, 12B, 12C, 12D, 12E, and 12F, another example process for forming a (HfO₂)-based ferroelectric material in a device 700 is shown. In FIG. 12A, the device 700 includes a substrate (e.g., one or more underlying layers) 704 and an interfacial/insulator layer 708 (referred to hereinafter as an insulator layer) arranged on the underlying layers 704. For example, the underlying layers 704 comprise silicon (Si). In some examples, the insulator layer 708 includes silicon dioxide (SiO₂) or silicon oxynitride (SiON) dielectrics. In some examples, the insulator layer 708 is deposited using atomic layer deposition (ALD), chemical vapor deposition (CVD) or physical vapor deposition (PVD). In other examples, the insulator layer 708 may be formed via thermal oxidation of Si. For example, the insulator layer 708 may be formed by thermal oxidation of Si in an oxygen environment with a nitrogen species (e.g., N₂O or N₂) to form SiON, plasma nitridation of SiO₂, etc. The insulator layer 708 may be deposited in a different processing chamber than a chamber used to perform subsequent steps.

As shown in FIG. 12B, optional pretreatment of the insulator layer 708 is performed. The pretreatment may be performed in a same or different processing chamber as the deposition of the insulator layer 708. The pretreatment may include thermal treatment, plasma treatment, and/or a sequence of thermal and plasma treatment (e.g., a thermal treatment step followed by a plasma treatment step). The pretreatment removes defects (e.g., unbonded hydrocarbon contaminants) from the surface of the insulator layer 708 as described above in FIG. 11B.

As shown in FIG. 12C, one or more ALD cycles are performed to deposit one or more thin layers 710 of HfO₂ (e.g., 0.1-2.0 nm HfO₂ ) on the insulator layer 708. For example, these initial ALD cycles may be performed at a temperature of 180-300° C. and a pressure of 0.1 to 2.0 Torr with an ozone dose time of 10-60 seconds, a precursor dose time of 1-5 seconds, and a purge time (i.e., to purge the precursor and ozone) of 30-75 seconds. In some examples, the ozone dose time is greater than the ozone dose time of FIG. 12E. For example, the ozone dose time of FIG. 12C is 45-60 seconds while the ozone does time of FIG. 12E is 10-45 seconds. The increased ozone dose time for the initial ALD cycles may minimize oxygen vacancies at the interface of the insulator layer 708 and the thin layers 710 of HfO₂.

As shown in FIG. 12D, treatment of the deposited layers 710 of HfO₂ layer is performed. Treatment may include thermal treatment, plasma treatment, and/or a sequence of thermal and plasma treatment (e.g., a thermal treatment step followed by a plasma treatment step) as described above in FIG. 11B.

As shown in FIG. 12E, remaining layers of HfO₂ are deposited on the layers 710 to form an HfO₂ layer 712 and a top electrode 716 is deposited on the HfO₂ layer 712. In some examples, the deposited HfO₂ layer 712 has a thickness in a range from 2 nm to 12 nm. In some examples, the HfO₂ layer 712 is doped using a dopant species selected from a group consisting of silicon (Si), aluminum (Al), yttrium (Yt), zirconium (Zr), and/or lanthanum (La). In some examples, the HfO₂ layer 712 is deposited using atomic layer deposition (ALD), although other processes can be used. For example, thermal ALD or plasma-enhanced ALD can be used. In some examples, the HfO₂ layer 612 is undoped. In other examples, the HfO₂ layer 712 is doped to a predetermined doping level from greater than 0 mol % to less than or equal to 60 mol % of the selected dopant species. In some examples, the HfO₂ layer 712 is doped to a predetermined doping level from 3 mol % to 5 mol % of the selected dopant species. The HfO₂ layer 712 may be amorphous.

Additional plasma treatment of the completed HfO₂ layer 712 may optionally be performed. For example, the HfO₂ layer 712 is nitridated by plasma including a nitrogen gas species. For example, molecular nitrogen (N₂) gas may be used. In some examples, the nitridation is performed during a predetermined period in a range from 15 s to 60 s. In some examples, the RF power may be in a range from 100 W to 15 kW. In some examples, the plasma power is in a range from 500 W to 1200 W. In some examples, the RF frequency may be in a range from 1 MHz to 15 MHz. In some examples, the RF frequency is 2.0 MHz and/or 13.56 MHz.

The top electrode 716 is deposited on the HfO₂ layer 712. In some examples, the top electrode 716 includes TiN, TaN, Ir or W, although other electrode materials can be used (e.g., Pt, Au, Pd, Al, Mo, Ni, Ti, etc.). In some examples, the top electrode 716 is deposited using atomic layer deposition (ALD), chemical vapor deposition (CVD), or physical vapor deposition (PVD). After depositing the top electrode 716, the device 700 is annealed at a predetermined temperature in a range from 500° C. to 1100° C. In other examples, the annealing temperature is in a range from 800° C. to 1000° C.

After annealing, the top electrode 716 is patterned as shown in FIG. 12F. For example, a mask is deposited, the top electrode 716 is etched, and the mask is removed after etching in a manner similar to that described in FIGS. 11D, 11E, and 11F.

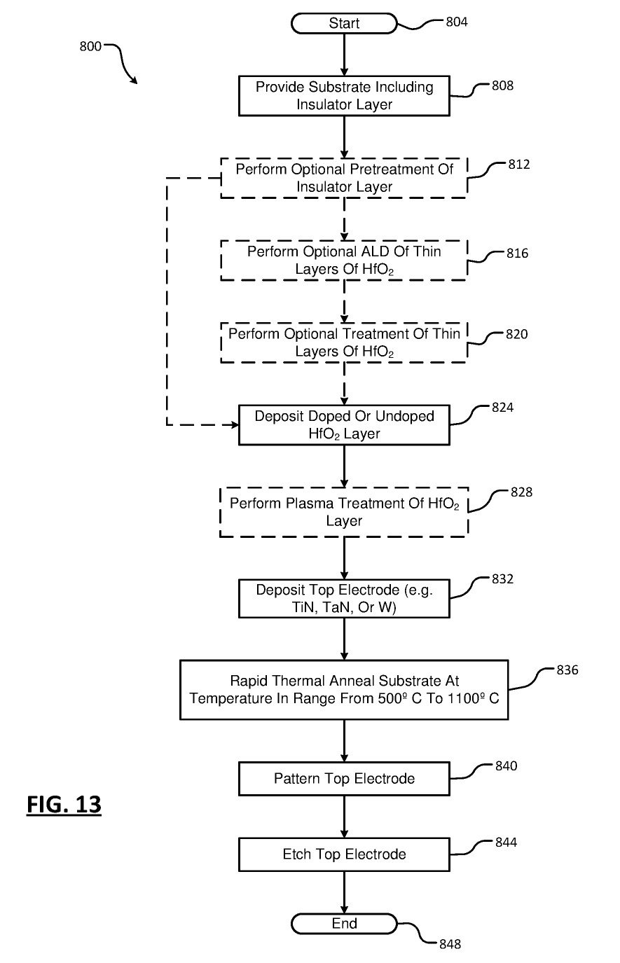

Referring now to FIG. 13, an example of a method 800 for pretreating an insulator layer and/or treating one or more HfO₂ layers according to the present disclosure begins at 804. At 808, a substrate is provided. For example, a substrate including one or more underlying layers and an insulator layer is arranged on a substrate support in a processing chamber. The insulator layer may include silicon dioxide (SiO₂) or silicon oxynitride (SiON). For example, the interfacial layer may be deposited using atomic layer deposition (ALD), chemical vapor deposition (CVD), or physical vapor deposition (PVD) in the same processing chamber or in a different processing chamber.

At 812, optional pretreatment of the insulator layer is performed. For example, the pretreatment may include thermal treatment and/or plasma treatment as described above in FIG. 11B. In examples where optional treatment of deposited layers of HfO₂ is performed, the method 800 continues to 816 and 820. Otherwise, the method 800 continues to 824. At 816, one or more cycles of ALD are performed to deposit thin layers of HfO₂ as described above in FIG. 12C. At 820, treatment of the deposited layers of HfO₂ is performed. For example, the treatment of the deposited layers of HfO₂ may include thermal treatment and/or plasma treatment as described above in FIG. 12D. Accordingly, at 812, 816, and 820, the method 800 performs pretreatment of the insulator layer and/or treatment of deposited thin layers of HfO₂. In other words, the method 800 may perform only pretreatment of the insulator layer, only treatment of deposited thin layers of HfO₂ , or both pretreatment of the insulator layer and treatment of deposited thin layers of HfO₂.

At 824, a doped or undoped HfO₂ layer is deposited on the insulator layer (e.g., using ALD) or on thin layers of HfO₂ previously deposited on the insulator layer at 816 and 820. At 828, plasma treatment of the HfO₂ layer may optionally be performed. For example, the HfO₂ layer may be nitridated by plasma including a nitrogen gas species. At 832, a top electrode (e.g., TiN, TaN, Ir or W) is deposited on the HfO₂ layer. For example, the top electrode is deposited using atomic layer deposition (ALD), chemical vapor deposition (CVD), or physical vapor deposition (PVD). At 836, the substrate, insulator layer, HfO₂ layer, and top electrode are annealed at a predetermined temperature in a range from 500° C. to 1100° C. (e.g., from 800° C. to 1000° C. ) to form ferroelectric HfO₂. The top electrode may be patterned at 840 (e.g., a mask may be patterned onto the top electrode) and etched at 844. The method 800 ends at 848.

### EXAMPLES

In one example, an SiO₂ insulator layer was pretreated with ozone (i.e., prior to performing any HfO₂ ALD cycles) in an ALD processing chamber at an ALD temperature (e.g., 200° C.). In this example, leakage current was reduced slightly. Conversely, in an example where the treatment with ozone was performed subsequent to 5-9 cycles HfO₂ ALD (e.g., 0.5 -0.9 nm), leakage current was reduced a greater amount relative to the sample where the insulator layer was pretreated. Leakage current reduction is indicative of fewer defects in the film stack, which suggests improved C-V hysteresis in MFIS switching.

In another example, conditions for depositing the initial thin layers (e.g., 2 nm) of HfO₂ may be varied to decrease defects. For example, an O₃ dose time during the initial ALD cycles (e.g., for the first 2 nm) may be greater than the O₃ dose time of ALD cycles performed subsequent to treatment. Accordingly, a leakage feature in ferroelectric switching is suppressed. In an example with the same O₃ dose time for ALD cycles prior to and subsequent to treatment, no FE hysteresis was observed in the C-V curve despite FE switching in the P-E curve. The absence of C-V hysteresis may be attributed to high defect density at the insulator/ferroelectric interface. Charge injection cancels the effect of FE switching. In contrast, in an example with a longer O₃ dose in the first 2 nm of HfO₂ prior to treatment, a memory window of 0.2 V was observed in the C-V curve. The extended O₃ dose time in the first 2 nm decreases the defect density at the interface, and therefore suppresses the charge injection. A memory window, although small, occurred in the C-V curve to indicate ferroelectric switching.

In another example, a forming gas anneal (FGA) step was performed on the substrate prior to performing the HfO₂ ALD. FGA performed at 300° C. prior to ALD did not further improve the leakage. However, the memory window increased from ˜0.3 V in the sample without FGA to ˜0.55 V in the sample with FGA performed prior to ALD. Accordingly, combining the pretreatment and treatment methods described herein with FGA may further increase the memory window (e.g., to 1.0 V).

In these described examples, the sample included an 8 nm HfO₂ layer with 4.2 mol % Si. The HfO₂ thickness may vary from 2 to 12 nm. The HfO₂ layer may be undoped or contain dopants such as Al, Y, Gd, Sr, La, and Zr. The dopant concentration varies between 0 and 6 mol % for Si, while other dopants may have a wider range of 0-60 mol %. Ferroelectric HfO₂ is formed by annealing with a metal cap (e.g. TiN) under N₂ at 600-1000° C.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method of forming ferroelectric hafnium oxide (HfO₂) in a substrate processing system, the method comprising:
arranging a substrate within a processing chamber of the substrate processing system;
depositing an HfO₂ layer on the substrate;
performing a plasma treatment of the HfO₂ layer; and
annealing the HfO₂ layer to form ferroelectric hafnium HfO₂.

2. The method of claim 1, wherein the HfO₂ layer is deposited using atomic layer deposition (ALD).

3. The method of claim 1, further comprising doping the HfO₂ layer.

4. The method of claim 3, wherein doping the HfO₂ layer includes doping the HfO₂ layer with at least one of silicon, aluminum, yttria, lanthanum, and zirconium.

5. The method of claim 3, wherein doping the HfO₂ layer includes doping the HfO₂ layer with between 0 and 5 mol % of a dopant species.

6. The method of claim 1, wherein depositing the HfO₂ layer includes alternating cycles of depositing HfO₂ onto the substrate and doping the deposited HfO₂.

7. The method of claim 1, wherein a thickness of the HfO₂ layer is between 6 and 12 nm.

8. The method of claim 1, further comprising alternating cycles of depositing the HfO₂ layer and performing the plasma treatment of the HfO₂ layer.

9. The method of claim 1, wherein performing the plasma treatment includes using at least one plasma gas species to perform the plasma treatment, wherein the at least one plasma gas species includes at least one of molecular nitrogen (N₂), ammonia (NH₃), molecular oxygen (O₂), ozone (O₃), argon (Ar), and argon and molecular hydrogen (Ar/H₂).

10. The method of claim 1, wherein performing the plasma treatment includes performing the plasma treatment with molecular nitrogen (N₂), and wherein performing the plasma treatment with N₂ causes HfOₓN_{y} to form on a surface of the HfO₂ layer.

11. The method of claim 1, wherein performing the plasma treatment includes performing the plasma treatment for between 15 and 60 seconds.

12. The method of claim 1, wherein performing the plasma treatment includes performing the plasma treatment at a radio frequency (RF) power between 500 and 1200 watts.

13. The method of claim 12, wherein the RF power is provided at between 1 and 15 MHz.

14. The method of claim 1, wherein annealing the HfO₂ layer includes annealing the HfO₂ layer at a temperature between 500 and 1100° C.

15. The method of claim 1, wherein annealing the HfO₂ layer includes annealing the HfO₂ layer at a temperature between 800 and 1000° C.

16. The method of claim 1, further comprising depositing a top electrode on the HfO₂ layer prior to the annealing.

17. The method of claim 16, wherein the top electrode comprises at least one of tantalum nitride, titanium nitride, and tungsten.

18. The method of claim 1, wherein depositing the HfO₂ layer on the substrate includes depositing the HfO₂ layer on one of an underlying layer and a bottom electrode formed on the substrate.

19. A method of treating a substrate including ferroelectric hafnium oxide (HfO₂) in a substrate processing system, the method comprising:
arranging a substrate within a processing chamber of the substrate processing system, wherein the substrate includes an insulator layer;
performing at least one of a thermal treatment and a plasma treatment of the insulator layer;
depositing an HfO₂ layer on the insulator layer; and
annealing the HfO₂ layer to form ferroelectric hafnium HfO₂.

20. The method of claim 19, wherein the insulator layer includes one of silicon dioxide (SiO₂) and silicon oxynitride (SiON).

21. The method of claim 19, wherein performing the at least one of the thermal treatment and the plasma treatment includes sequentially performing the thermal treatment and the plasma treatment.

22. The method of claim 19, wherein performing the at least one of the thermal treatment and the plasma treatment includes increasing a temperature of the substrate to between 200 and 600° C. for 1 to 30 minutes.

23. The method of claim 19, wherein performing the at least one of the thermal treatment and the plasma treatment includes providing at least one of N₂, N₂/H₂, NH₃, O₂, and O₃ to the processing chamber.

24. The method of claim 19, further comprising performing a plasma treatment of the HfO₂ layer.

25. The method of claim 19, wherein the HfO₂ layer is deposited using atomic layer deposition (ALD).

26. The method of claim 19, further comprising doping the HfO₂ layer.

27. A method of treating a substrate including ferroelectric hafnium oxide (HfO₂) in a substrate processing system, the method comprising:
arranging a substrate within a processing chamber of the substrate processing system, wherein the substrate includes an insulator layer;
depositing at least one first HfO₂ layer on the insulator layer;
performing at least one of a thermal treatment and a plasma treatment of the at least one first HfO₂ layer;
depositing at least one second HfO₂ layer on the at least one first HfO₂ layer; and
annealing the at least one second HfO₂ layer and the at least one first HfO₂ layer to form a ferroelectric hafnium HfO₂ layer.

28. The method of claim 27, wherein the insulator layer includes one of silicon dioxide (SiO₂) and silicon oxynitride (SiON).

29. The method of claim 27, wherein performing the at least one of the thermal treatment and the plasma treatment includes sequentially performing the thermal treatment and the plasma treatment.

30. The method of claim 27, wherein performing the at least one of the thermal treatment and the plasma treatment includes increasing a temperature of the substrate to between 200 and 600° C. for 1 to 30 minutes.

31. The method of claim 27, wherein performing the at least one of the thermal treatment and the plasma treatment includes providing at least one of N₂, N₂/H₂, NH₃, O₂, and O₃ to the processing chamber.

32. The method of claim 27, wherein the at least one first HfO₂ layer is deposited in accordance with a dose time that is greater than a dose time used to deposit the at least one second HfO₂ layer.

33. The method of claim 27, further comprising performing at least one of a thermal treatment and a plasma treatment of the insulator layer prior to depositing the at least one first HfO₂ layer.

34. The method of claim 27, wherein the at least one first HfO₂ layer and the at least one second HfO₂ layer are deposited using atomic layer deposition (ALD).
